(19) United States
(12) Patent Application Publication
(10) Pub. No.: US 2011/0180317 A1
(43) Pub. Date: Jul. 28, 2011

(54) ELECTRONIC COMPONENT PACKAGE, METHOD FOR PRODUCING THE SAME AND INTERPOSER

(76) Inventors: Eiji Takahashi, Nara (JP); Yoshiyuki Saito, Osaka (JP)

(21) Appl. No.: 13/122,603

(22) PCT Filed: Aug. 5, 2010
(86) PCT No.: PCT/JP2010/004933

§ 371 Date: Apr. 5, 2011

(30) Foreign Application Priority Data
Sep. 11, 2009 (JP) 2009-210468

(51) Int. Cl. H01L 23/495

(52) U.S. Cl. 174/537

(57) ABSTRACT

A package comprising an electronic component, a circuit substrate onto which the electronic component is mounted, and an interposer located between the electronic component and the circuit substrate, allowing them to be electrically connected with each other, wherein the interposer is composed of at least two sub-interposers, and the at least two sub-interposers lie in the same plane to be disposed only on electrode terminal-forming areas of both of the electronic component and the circuit substrate.

### TECHNICAL FIELD

The present invention relates to an electronic component package, a method for producing the package and an interposer used for the package. More particularly, the present invention relates to an electronic component package wherein fan-out is provided by an interposer, a method for producing such package and an interposer used therefor.

### BACKGROUND OF THE INVENTION

In a package where an integrated circuit (IC) device is mounted on a printed circuit substrate, the miniaturized IC device can be configured to have a small terminal pad area and a small pad pitch. In many cases, the IC device thus has a fine pitch of the terminal pad. However, the printed circuit substrate which constitutes a system is generally configured to have a much larger pad pitch, as compared with that of the IC device. An interposer can connect the printed circuit substrate and the IC device with each other. In this regard, the interposer with its pitch similar to the pad pitch of the IC is extremely expensive or such interposer does not exist. Thus, silicon interposer is sometimes used because they are made of silicon which is a base material of IC devices, and thus can be obtained by a production process of the IC devices. In this case, the silicon interposer makes it possible to mount the IC device to or onto the print circuit substrate at low cost by locating it between the IC device and the printed circuit substrate.

As illustrated in FIG. 11, a silicon interposer 800 of the prior art electrically interconnects “device 810 (e.g. IC device)” disposed on its upper surface and “sub system 820 (e.g. printed circuit substrate)” disposed on its lower surface. Terminal Contacts on the upper surface of the interposer 800 align with terminal pads of the device 810, and thereby forming electric interconnection stacks 815 which serve to connect the device 810 with the interposer 800. While on the other hand, terminal contacts on the lower surface of the interposer 800 align with corresponding contacts on the subsystem 820, and thereby forming electric interconnection stacks 825. As illustrated in FIG. 11, the interposer 800 has a higher interconnection density on its upper surface than that on its lower surface. Namely, the interposer 800 fanwise spreads its interconnection density from the terminal pad of the device 810 to the subsystem 820 so as to fit it to the interconnection density of the subsystem 820. Such fan-like spread pattern of the interposer may be formed by a layered metal coating method or by a combination with a structure of through-hole via.

### PATENT DOCUMENTS

[Patent document 1] Japanese Unexamined Patent Publication (Kokai) No. 2004-282072

### SUMMARY OF THE INVENTION

### Problems to be Solved by the Invention

In conventional mount structures as described above, the silicon interposer has a larger area than that of the device. Such silicon interposer is also configured to entirely cover the outermost area of a terminal pad array of the device. In these regards, refer to FIG. 12 for example. The silicon interposer does not have integrated active elements or complicated wirings, but just has wiring for interconnecting contacts of the device and contacts of the component to which the interposer is connected (see FIG. 11). The large area or large volume of the interposer is not used for those of wiring, although the cost of interposer mostly depends on their area and volume. This means that the larger unused area or volume of the interposer causes a larger disadvantage in terms of cost.

Under the above circumstances, the present invention has been created. That is, an object of the present invention is to provide a package with a satisfactory mounting efficiency wherein an interposer (in particular a silicon interposer) is used, and also to provide a production process thereof.

### Means for Solving the Problem

In order to achieve the above object, the present invention provides a package comprising:

an electronic component comprising a plurality of electrode terminals;

a circuit substrate comprising a plurality of electrode terminals, onto which the electronic component is mounted; and

an interposer located between the electronic component and the circuit substrate, allowing them to be electrically connected with each other,

wherein the interposer is composed of at least two sub-interposers; and

the at least two sub-interposers lie in the same plane such that they are disposed only on electrode terminal-forming areas of both of the electronic component and the circuit substrate.

For one thing, the package of the present invention is characterized in that the interposer is not a single one but is composed of a plurality of the divided sub-members (i.e. separate sub-interposers), and that the divided sub-members are positioned only on “electrode terminal-forming areas” of the electronic component and the circuit substrate. In other words, the divided sub-members, i.e. the sub-interposers are not disposed on the areas other than the “electrode terminal-forming area”. The at least two sub-interposers are separated sub-members, and thus it is preferred that they are ones which are cut out from the same base part and are made of the same material as each other (namely, each sub-interposers has an insulating body of the same material).

As used herein, “interposer” substantially means a sheet member or board member which enables a fan-out or pad pitch expansion. That is, the term “interposer” as used in the present description and claims substantially represents a substrate for changing a pitch of the electrode terminals upon mounting an electronic component onto a circuit substrate, and thereby electrically interconnect the electronic component and the circuit substrate via such interposer.

As used herein, “electrode terminal-forming area” substantially means “local surface area of an electronic component, where electrode terminals thereof are formed” or “local surface area of a circuit substrate, where electrode terminals thereof are formed”. For example, the term “electrode terminal-forming area” represents a limited area surrounding the electrode terminals as illustrated in FIGS. 1(a) and 1(b) (namely, it represents the areas surrounded by the dotted line in FIGS. 1(a) and 1(b)). Accordingly, the phrase “disposed only on electrode terminal-forming areas” as used in the present description and claims substantially means that an interposer is provided only in a limited area which covers the electrode terminal-forming areas of both of the electronic component and the circuit substrate. For example, the limited area represented by reference numeral 400 in FIG. 1(c) corresponds to not only the electrode terminal-forming area of the electronic component, but also the electrode terminal-forming area of the circuit substrate.

As used in the present description and claims, the phrase “lie in the same plane” means in a broad sense that all of a plurality of the sub-interposers are arranged along the direction perpendicular to the facing direction in which the circuit substrate and the electronic component are opposed to each other. Specifically in a limited sense, such phrase means that all of a plurality of the sub-interposers are located between the circuit substrate and the electronic component.

In one preferred embodiment, the electronic component is a semiconductor chip and at least two sub-interposers contain a semiconductor material which constitutes the semiconductor chip. The semiconductor material may be at least one material selected from the group consisting of silicon (Si), germanium (Ge), selenium (Se), tellurium (Te) and the like. For example, a semiconductor production process using a silicon wafer can provide not only a semiconductor but also the sub-interposers which contain a silicon material.

The arrangement of “at least two sub-interposers” is not particularly limited as long as it covers only “electrode terminal-forming areas” of the electronic component and the circuit substrate. For example, with respect to the arrangement of “at least two sub-interposers”, the at least two sub-interposers may be spaced from each other in the same plane. The at least two sub-interposers may also be arranged in a form of ring in the same plane.

The present invention also provides a method for producing the electronic component package as described above (i.e. interposer package). This production method of the present invention comprises the steps of:

(i) providing a wafer (namely providing a base part);

(ii) cutting the wafer to produce a plurality of interposer precursors;

(iii) forming conductive portions in each of the interposer precursors to electrically interconnect the opposed surfaces thereof, and thereby producing a plurality of sub-interposers;

(iv) mounting at least two of the sub-interposers onto a circuit substrate; and

(v) mounting an electronic component onto the at least two of the sub-interposers onto a circuit substrate,

wherein in the step (iv), the at least two of the sub-interposers are mounted such that they are disposed on an electrode terminal-forming area of the circuit substrate; and

in the step (v), the electronic component are mounted such that the at least two of the sub-interposers are disposed on an electrode terminal-forming area of the electronic component.

For one thing, the production method of the present invention is characterized in that the interposer is divided into a plurality of pieces or sub-members (i.e. sub-interposers) and to dispose the divided members only onto the electrode terminal-forming areas of the electronic component and the circuit substrate.

In one preferred embodiment, the electronic component used in the step (v) is a semiconductor chip, and the semiconductor chip is provided from the wafer prepared in the step (i). That is, it is intended to obtain the interposer during a semiconductor production process, i.e. by making use of a process for producing the semiconductor chip.

In another preferred embodiment, two types of packages, a first package comprising a first interposer and a second package comprising a second interposer are produced. In this embodiment, the cutting of the wafer is performed in the step (ii) by a combination of plural linear dicing operations, wherein a plurality of interposer precursors for the first interposer and a plurality of interposer precursors for the second interposer are provided while making use of the whole of the rectangular wafer provided in the step (i). It is intended in this embodiment to effectively use the wafer by providing as many pieces as possible per wafer. In general, two different packages in size can be obtained (from an another viewpoint, two different interposers in term of size and shape can be obtained).

Furthermore, the present invention also provides an interposer used in the above package as well as the above production method thereof. The interposer of the present invention is characterized in that it is composed of at least two sub-interposers, each of which has a first surface and a second surface which is opposed to the first surface, and that terminal contact provided on the first surface is electrically connected with terminal contact provided on the second surface in each of the sub-interposers.

### Effect of the Invention

In accordance with the present invention, there is provided an electronic component package using an interposer and a production process of the package with a satisfactory mounting efficiency. Specifically, according to the present invention, the interposer is provided as divided sub-members only in a limited region where a fan-out or pad pitch expansion is really required (i.e. the volume of the interposer is accordingly reduced). As a result, a low-cost of the mounting is achieved. In other words, even if an electronic component with fine pitch pad is mounted onto a circuit substrate, the mounting cost is low due to “at least two sub-interposers” which is placed therebetween.

In accordance with the package of the present invention, the interposer is composed of “separately divided sub-members”, and thus an influence of a thermal expansion or thermal contraction is small as a whole. In this regard, if the interposer is provided as a comparatively large single one, then the influence of the thermal expansion or contraction can become larger, and thereby causing a thermal influence such as “warpage” of the interposer. While on the other hand, when the interposer is divided and thus the small sub-members of the interposer are used, then the thermal influence such as “warpage” becomes relatively low, making it possible to effectively reduce or prevent the thermal expansion or thermal contraction of the interposer.

Moreover, even if some defect of the interposer occurs during the production process, it is not necessary to exchange the whole interposer. A particular sub-interposer where the defect really occurs is only changed since the interposer is divided into sub-interposers. That is, the interposer according to the invention can contribute to an improved yield rate of the package production, and thus is advantageous in terms of cost.

### BRIEF DESCRIPTION OF THE DRAWINGS

FIG. 1 illustrates schematic views for explaining “electrode terminal-forming area” wherein FIG. 1(a) is a plan view of a circuit substrate, FIG. 1(b) is a plan view of an electronic component and FIG. 1(c) is a plan view of a package.

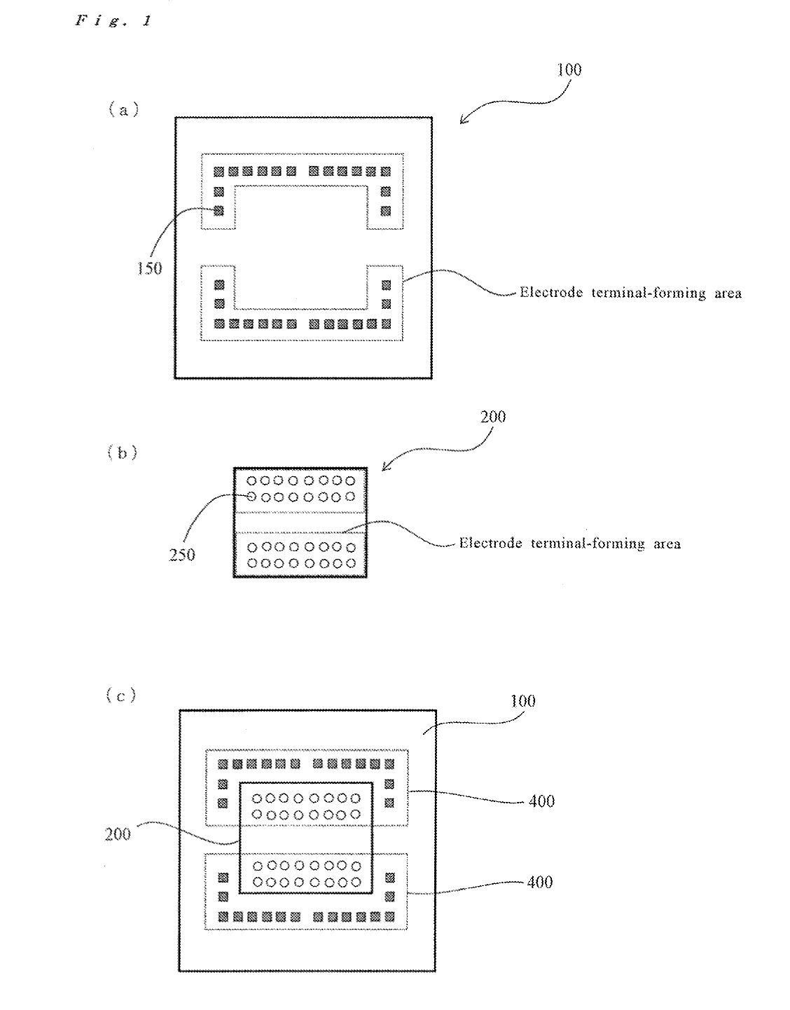

FIG. 2 illustrates an external view which schematically shows a package of the present invention (FIG. 2(a)), and also illustrates a developed view thereof (FIG. 2(b)).

FIG. 3 illustrates a perspective view (FIG. 3(a)) and a plan view (FIG. 3(b)), each schematically showing a circuit substrate.

FIG. 4 illustrates a perspective view (FIG. 4(a)) and a plan view (FIG. 4(b)), each schematically showing an electronic component.

FIG. 5 illustrates a perspective view (FIG. 5(a)), plan views (FIGS. 5(b) and 5(c)) and transparent view (FIG. 5(d)), each schematically showing a sub-interposer.

FIG. 6 illustrates schematic views for explaining a size of an electrode terminal-forming area, wherein FIG. 6(a) is a plan view of a circuit substrate and FIG. 6(b) is a plan view of an electronic component.

FIG. 7 illustrates a schematic view showing an embodiment where two sub-interposers are spaced from each other in the same plane.

FIG. 8 illustrates a schematic view showing an embodiment where four sub-interposers are provided in the same plane to form a ring thereby.

FIG. 9 illustrates schematic views for explaining a preferred dicing of sub-interposer precursors, wherein FIG. 9(a) is a plan view of a rectangular wafer, FIG. 9(b) is a plan view showing dicing lines, FIG. 9(c) is a plan view of sub-interposer precursors which have been cut out and FIG. 9(d) is a plan view of packages produced from the sub-interposer precursors of FIG. 9(c).

FIG. 10 illustrates a plan view for explaining “cutting out” of the sub-interposer precursors of FIG. 9.

FIG. 11 illustrates a sectional view schematically showing a silicon interposer of the prior art.

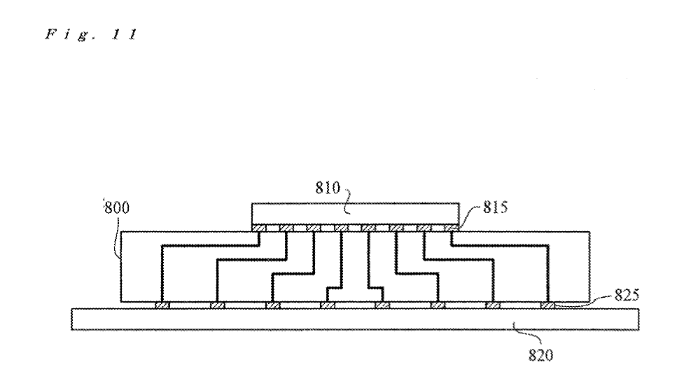

FIG. 12 illustrates a sectional view (FIG. 12(a)) and a plan view (FIG. 12(b)), each schematically showing a package of the prior art.

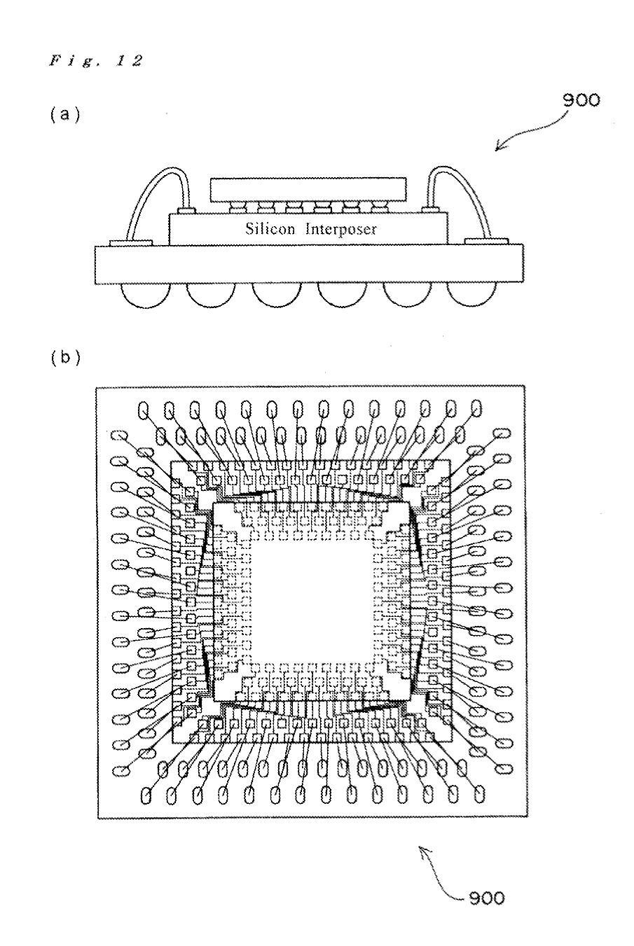

### EXPLANATION OF REFERENCE NUMERALS

100: circuit substrate
100a, 100b: opposed surfaces of circuit substrate
150: electrode terminal of circuit substrate
150A, 150B: electrode terminal-forming area of circuit substrate:
200: electronic component
200a, 200b: opposed surfaces of electronic component
250: electrode terminal of electronic component
250A, 250B: electrode terminal-forming area of electronic component
300: interposer
300A, 300B, 300C, 300D . . . : sub-interposer
300A′, 300A″: opposed surfaces of sub interposer
350: conductive portion
350A′: terminal contact connected to electrode terminal of electronic component
350A″: terminal contact connected to electrode terminal of circuit substrate
400: electrode terminal-forming area which covers electrode terminals of electronic component and circuit substrate
500: wafer (rectangular wafer)
600A, 600B: sub-interposer precursor
1000: package of the present invention
1000A, 1000B: packages of the present invention
800: silicon interposer of the prior art
810: device (IC device)
815: connection stack
820: subsystem (printed circuit substrate)
825: electrical interconnection stack
900: package of the prior art

### DETAILED DESCRIPTION OF THE INVENTION

The present invention will be described in detail below with reference to the accompanying drawings. First, a package of the present invention will be described, and then a production method of the present invention will be described. A description about an interposer of the present invention is accompanied with the description on the package of the present invention.

### [Package of the Present Invention]

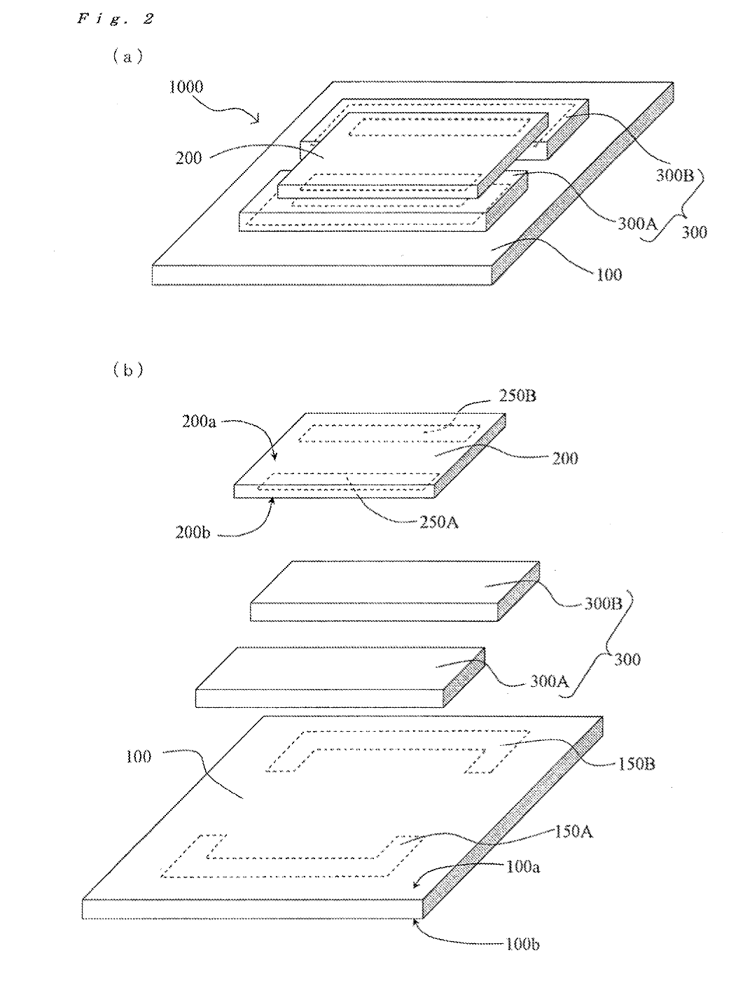

FIGS. 2(a) and 2(b) illustrate an external view and developed view of a package 1000 according to the present invention. As illustrated in FIGS. 2(a) and 2(b), the package 1000 of the present invention is mainly composed of a circuit substrate 100, an electronic component 200 and an interposer 300. In the package 1000 of the present invention, the electronic component 200 is mounted on the circuit substrate 100 wherein the interposer 300 is located between the circuit substrate 100 and the electronic component 200 to electrically interconnect them.

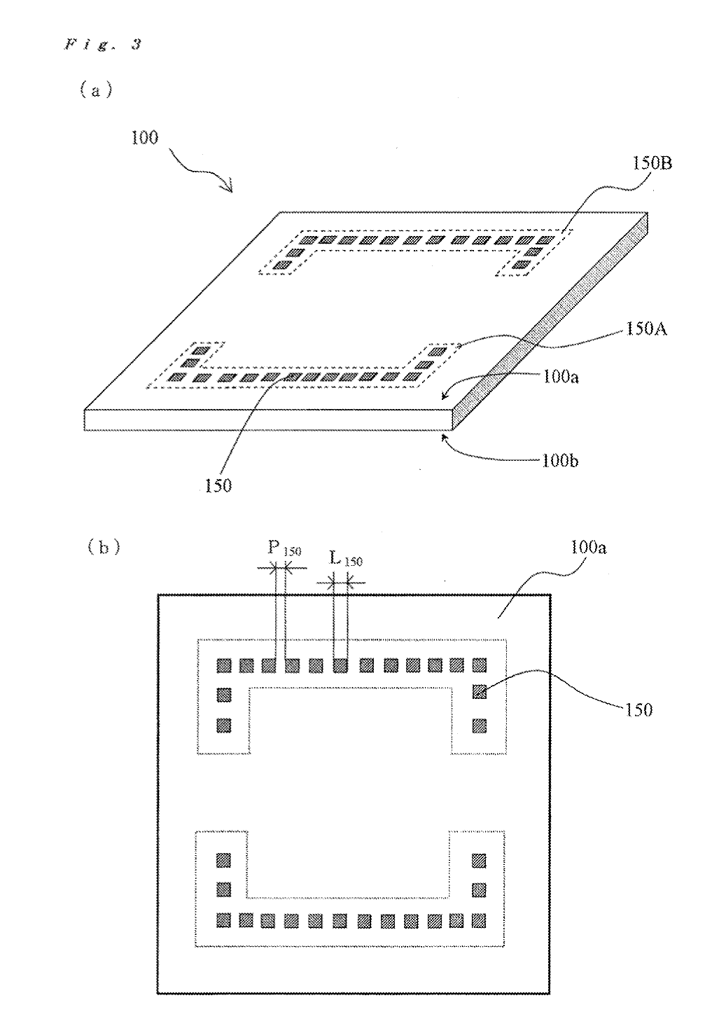

As illustrated in FIGS. 3(a) and 3(b), the circuit substrate 100 includes a plurality of electrode terminals 150 on its surface 100a facing the electronic component 200 in a package. The circuit substrate is not particularly limited as long as it is one used in common mounting techniques. Examples of the circuit substrate include a printed circuit substrate. The electrode terminals 150 of the circuit substrate are not particularly limited in terms of its size and pitch as long as they correspond to values which are similar to ones employed in common mounting techniques. For example, the electrode terminals 150 as illustrated in FIG. 3(b) has a size L₁₅₀ of preferably about 70 to 1000 μm, more preferably about 100 to 300 μm, and also has a pitch P₁₅₀ of preferably about 70 to 1000 μm, more preferably about 100 to 300 μm.

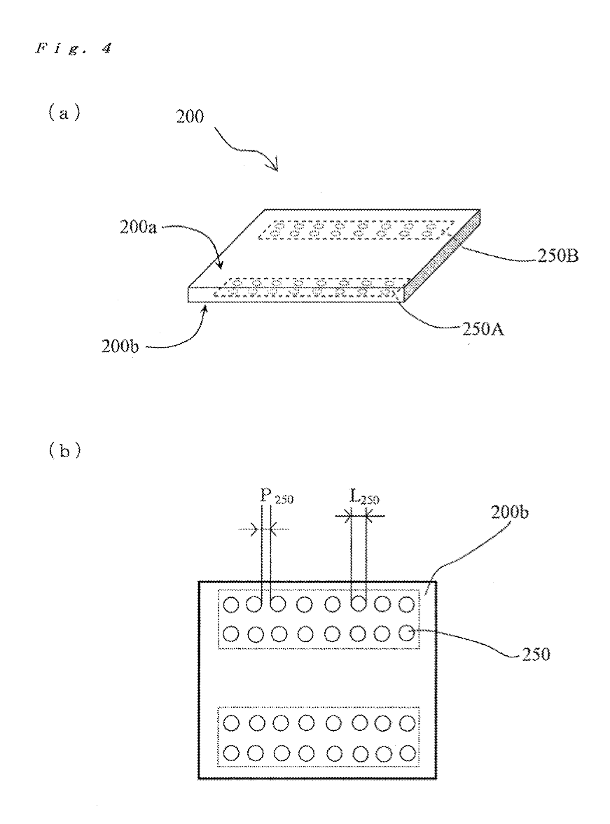

As illustrated in FIGS. 4(a) and 4(b), the electronic component 200 includes a plurality of electrode terminals 250 on its surface 200b facing the circuit substrate 100 in a package. The electronic component is not particularly limited as long as it is one used in common mounting techniques. Examples of the electronic component include an IC device, a semiconductor chip, a capacitor and the like. The electrode terminals 250 of the electronic component 200 are not particularly limited in terms of their size and pitch as long as they correspond to values which are similar to ones employed in common mounting techniques (in general, electronic components have finer pitch than that of circuit substrates). For example, the electrode terminals 250 as illustrated in FIG. 4(b) has a size L₂₅₀ of preferably about 50 to 200 μm, and also has a pitch P₂₅₀ of preferably about 20 to 100 μm.

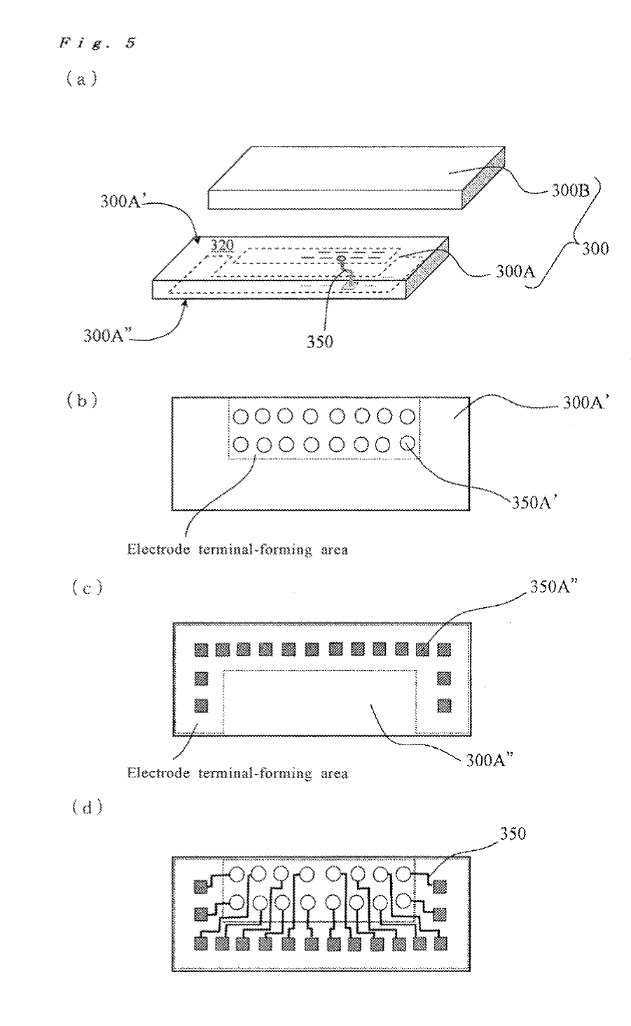

As illustrated in FIG. 5, the interposer 300 is composed of at least two sub-interposers (300A, 300B, . . . ). In FIG. 5, two sub-interposers are illustrated by way of example. This means that the interposer 300 used in the package of the present invention is not a single one, but is composed of a plurality of divided sub-members. As illustrated in FIGS. 5(a) and 5(b), each sub-interposer has a plurality of conductive portions 350 to electrically interconnect the opposed surfaces (i.e. “front face” and “back face”). In the package where the interposer is located between the electronic component and the circuit substrate, the conductive portions 350 are in contact with both of “electrode terminals 150 of circuit substrate 100” and “electrode terminals 250 of electronic component 200”. Accordingly, the circuit substrate 100 and the electronic component 200 are electrically interconnected via the conductive portions 350.

Each of the sub-interposers 300 (300A, 300B, . . . ) includes an insulating body 320 and the conductive portions 350. The insulating body 320 may be made of any materials as long as the insulation is ensured. For example, the insulating body 320 may include a silicon, a ceramic, an organic resin or the like. That is, the interposer 300 may be a silicon interposer, a ceramic interposer or an organic resin interposer. It is preferred that the silicon interposer can be obtained from a silicon wafer which is used in producing semiconductor elements or semiconductor chips. A ceramic interposer is also preferable in its low thermal distortion or a satisfactory high frequency property. An organic interposer is also preferable since the preparation thereof is relatively easy. Examples of the organic resin used for the organic resin interposer include a thermosetting resin, a thermoplastic resin, a photocurable resin and the like. For example, heat-resistant interposers can be obtained by using an epoxy resin, a phenol resin or a cyanate resin. The conductive portions 350 may be made of any materials as long as the electroconductivity is ensured. For example, the conductive portions 350 may be made of at least one conductive material selected from the group consisting of copper, gold, silver and nickel. Among them, the copper is particularly preferred due to its high electrical conductivity and its low migration.

It is preferred that each of the sub-interposers (300A, 300B, . . . ) has such a sheet- or board-shape that its thickness is smaller than the other dimensions thereof as illustrated in FIG. 5(a). The thickness (i.e. the distance between opposed surfaces 300A′ and 300A″ as illustrated in FIG. 5(a)) is not particularly limited, and is preferably in the range of about 150 to 500 μm, more preferably in the range of about 200 to 250 μm. It is preferred that a main faces of each of the sub-interposers (300A, 300B, . . . ) have a shape which corresponds to a combination of the electrode terminal-forming areas of the circuit substrate and the electronic component (see FIG. 5(d)).

The interposer 300 has connection terminals on its opposed surfaces. The connection terminals of the interposer are connected with electrode terminals of the circuit substrate and the electronic component. For example, as for the sub-interposer 300A illustrated in FIG. 5(a), terminal contacts 350A″ to be connected to the electrode terminals of the circuit substrate are provided on the face 300A″ which corresponds to a main face of the sub-interposer 300A facing the circuit substrate 100 (see FIG. 5(c)). While on the other hand, terminal contacts 350A′ to be connected to the electrode terminals of the electronic component are provided on the face 300A′ facing the electronic component 200 (see FIG. 5(b)). The terminal contacts 350A″ which is connected to the electrode terminals of the circuit substrate may have a size and pitch corresponding to the size and pitch (i.e. L₁₅₀ and P₁₅₀ in FIG. 3(b)) of the electrode terminals of the circuit substrate. While on the other hand, the terminal contacts 350A′ which is connected to the electrode terminals of the electronic component may have a size and pitch corresponding to the size and pitch (i.e. L₂₅₀ and P₂₅₀ in FIG. 4(b)) of the electronic component. In general, the terminal contacts 350A′, which is connected to the electrode terminals of the electronic component, have a finer pitch than that of the terminal contacts 350A″ which is connected to the electrode terminals of the circuit substrate. In other words, the terminal contacts 350A″ serving as being connected to the electrode terminals of the circuit substrate have a larger pitch than that of the terminal contacts 350A′ serving as being connected to the electrode terminals of the electronic component, which makes it possible to achieve a pitch conversion (in particular “fan-out”) by the sub-interposers.

In the package of the present invention, the interposer 300 is located between the circuit substrate 100 and electronic component 200, and thereby the circuit substrate 100 and electronic component 200 are electrically connected with each other. Specifically, in a case where two sub-interposers (300A and 300B) are provided as illustrated in FIG. 2(a) for example, a plurality of the terminal contacts 350A″ of the sub-interposer 300A are respectively connected to a plurality of the electrode terminals 150 of the circuit substrate 100 whereas a plurality of the terminal contacts 350A′ of the sub-interposer 300A are respectively connected to a plurality of the electrode terminals 250 of the electronic component 200. Similarly, a plurality of the terminal contacts 350B″ of the sub-interposer 300B are connected to a plurality of the electrode terminals 150 of the circuit substrate 100 whereas a plurality of the terminal contacts 350B′ of the sub-interposer 300B are connected to a plurality of the electrode terminals 250 of the electronic component 200. The connection between “terminal contacts of sub-interposers” and “electrode terminals of circuit substrate” and also the connection between “terminal contacts of the sub-interposers” and “electrode terminals of electronic component” are not particularly limited, and may be ones which are commonly employed in conventional mounting techniques using an interposer. For example, solder may be provided between the electrode terminals and terminal contacts in order to connect them with each other.

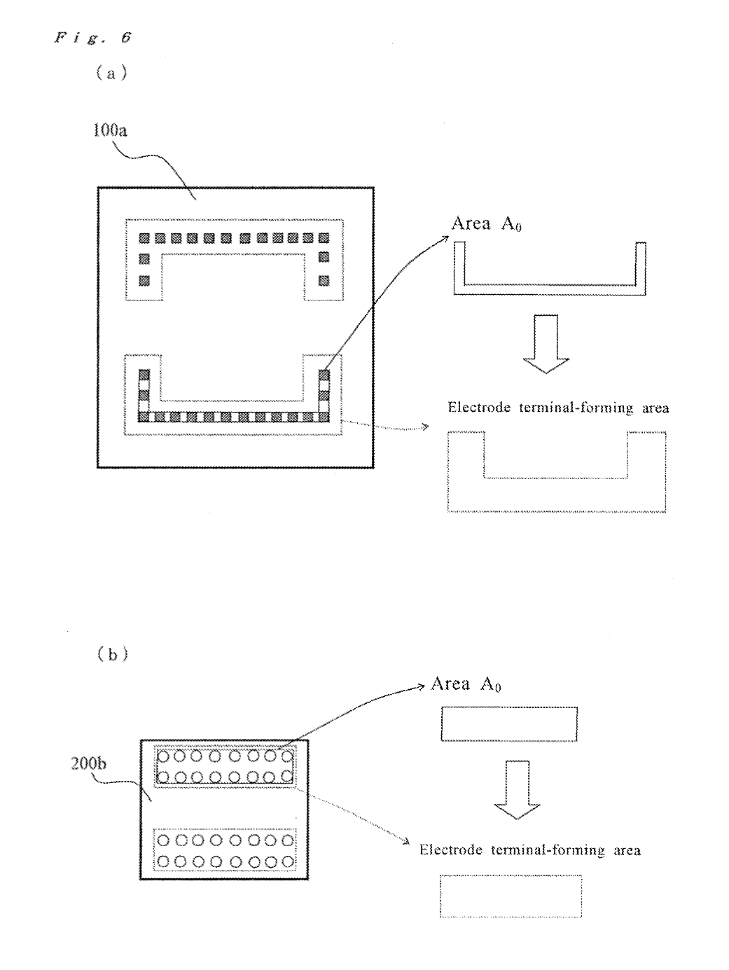

In the package of the present invention, a plurality of the sub-interposers are provided in the same plane such that their disposition covers only the electrode terminal-forming areas of the electronic component and the circuit substrate as illustrated in FIG. 2. As described above, “electrode terminal-forming area” substantially means a local area surrounding the electrode terminals. Specifically, “electrode terminal-forming area” means an area which includes at least the electrode terminals but is not larger than necessary. As illustrated in FIG. 6 for example, it means an area 1% to 40% larger than an area A₀, preferably 1% to 30% larger than an area A₀, more preferably 1% to 15% larger than an area A₀ wherein A₀ is a closed region surrounded by lines passing through edges or tangents of the electrode terminals.

In the mounting structure according to the present invention, the interposer is divided into a plurality of the sub-interposers so that the interposer is placed only on a limited region where the fan out is required. Therefore, it is possible to reduce “interposer area or interposer volume” as compared to an interposer composed of a single member, which leads to an achievement of reduction in material cost. Particularly in a case where the silicon interposer is used, a greater advantage of the cost reduction is provided since the silicon interposer can be obtained from a silicon wafer prepared upon a production of electronic components such as semiconductor chips.

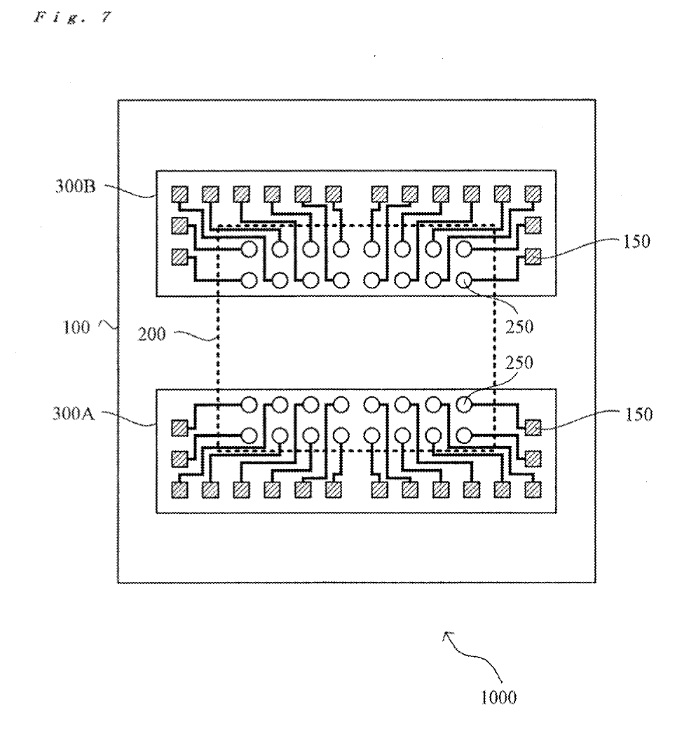

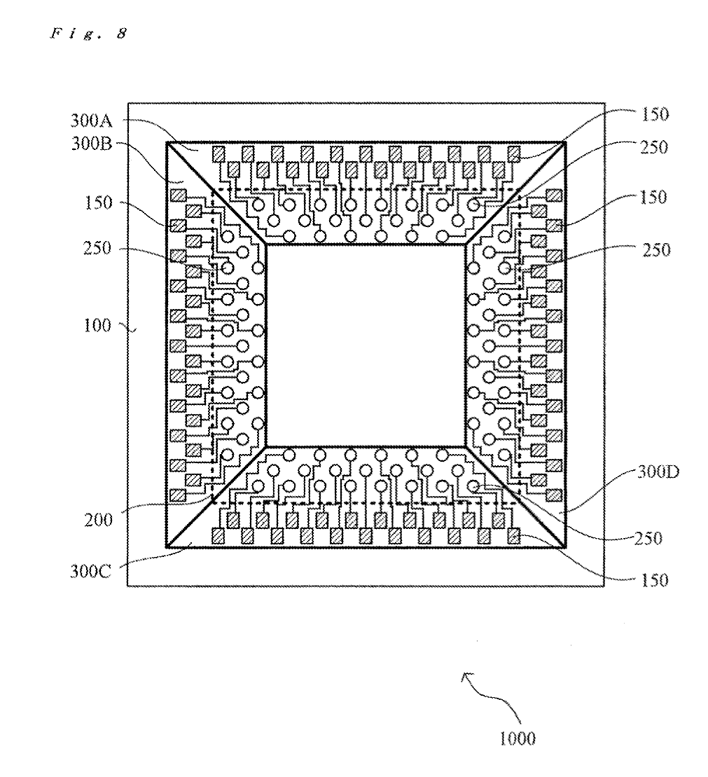

According to the package of the present invention, at least two sub-interposers lie in the same plane to be disposed only on the electrode terminal-forming areas of both of the electronic component and the circuit substrate. In this respect, there are numerous variations. For example, as illustrated in FIG. 7, the two sub-interposers (300A and 300B) may be symmetrically spaced from each other in the same plane. This can correspond to the embodiment as described with reference to FIGS. 2 to 6. Alternatively, the four sub-interposers (300A, 300B, 300C and 300D) symmetrically may lie in the same plane such that they are arranged in an annular pattern as illustrated in FIG. 8. In any of these cases, a plurality of the sub-interposers (300A, 300B, . . . ) are disposed only on the combined area of the electrode terminal-forming area of the circuit substrate and the electrode terminal-forming area of the electronic component.

### [Production Method of the Present Invention]

Next, the method for producing the electronic component package of the present invention will be described. For one thing, the production method of the present invention is characterized in that an interposer is divided into a plurality of pieces as sub-interposers (for example, the interposer is divided into 2 to 10 pieces) and the divided sub-interposers are provided only onto electrode terminal-forming areas of an electronic component and a circuit substrate.

First, the step (i) is performed. That is, a wafer is prepared. The wafer to be prepared may be a conventional wafer which is commonly used in a mounting of an electronic component. A commercially available wafer may be used. For example, taking a case of preparing a silicon wafer as an example, the wafer can be obtained by a crystal growth in the floating zone (Fz) process or Czochralski (Cz) process, followed by slicing, chamfering, polishing and the like.

Next, the step (ii) is performed. That is, the wafer is cut into pieces so as to obtain a plurality of interposer precursors. For example, a dicing of wafer is performed with a dicing saw so as to cut out pieces from the wafer, wherein the resulting pieces correspond to bodies of sub-interposers. It is preferred that the interposer precursors are each cut out so that they form a combined shape of the electrode terminal-forming areas of the circuit substrate and the electronic component.

Subsequent to the step (ii), the step (iii) is performed. That is, conductive portions for electrically interconnecting the opposed surfaces are formed in each interposer precursor. As a result, a plurality of sub-interposers are produced. The conductive portions may be formed by a method similar to a conventional method for forming conductive portions of an interposer in mounting techniques. That is, the conductive portions can be formed by a production process of a wiring pattern and/or a via hole conductor, such process being commonly used in the mounting field. This will be described in more detail. For example, a wiring pattern is made of an electrically conductive material, and can be made from those commonly used in a conventional production of semiconductor devices. For example, metal foils, conductive resin compositions, lead frames with processed metal foil and the like may be used. When a metal foil is used, a fine wiring pattern can be easily formed by an etching process or the like. In particular, a copper foil is preferable because of its low cost and high electrical conductivity. When a conductive resin composition is used, the wiring pattern can be formed by screen printing or the like. When the wiring pattern is formed by a lead frame, it is possible to use a metal with an appropriate its thickness and a low electrical resistance and it is possible to employ a simple production process such as a fine patterning process by an etching process, a punching process or the like. Another method for forming the wiring pattern may be a transfer method using a release film. In this case, it is easy to handle the wiring pattern since it is formed on the release film. While on the other hand, the via hole conductor can be formed by forming a via hole in the interposer precursors, followed by plating its inner surface or filling it with a conductive resin composition and then curing it according to need. The conductive resin composition may be a mixture of “metal particles consisting of gold, silver, copper, nickel or the like” and “thermosetting resin such as an epoxy resin, a phenol resin or a cyanate resin”.

Subsequent to the step (iii), the step (iv) is performed. That is, at least two of the sub-interposers are mounted onto the circuit substrate. It is particularly noted in this step that the at least two sub-interposers are mounted so that they are located only onto the electrode terminal-forming area of the circuit substrate. That is, upon connecting the conductive portions of each sub-interposer with the electrode terminals of the circuit substrate, the horizontal position of each sub-interposer is adjusted so that the sub-interposers are not placed onto an area other than the electrode terminal-forming area of the circuit substrate.

Subsequent to the step (iv), the step (v) is performed. That is, the electronic component is mounted onto the sub-interposers which have been placed on the circuit substrate. It is particularly noted in this step that the electronic component is mounted so that the at least two sub-interposers are located only on the electrode terminal-forming area of the electronic component. That is, upon connecting the electrode terminals of the electronic component with the conductive portions of each sub-interposer, the horizontal position of the electronic component is adjusted so that the sub-interposers are not located on an area other than the electrode terminal-forming area of the electronic component.

Through the above steps, the package 1000 as illustrated in FIGS. 7 and 8 can be finally obtained.

The production method of the present invention can achieve a greater advantage in terms of cost reduction when the interposer which can be produced during a production process of the electronic component is used. In other words, a greater reduction of cost is achieved when the electronic component used in the step (v) is a semiconductor chip and such semiconductor chip is obtained from the wafer prepared in the step (i).

Moreover, the production method of the invention makes it possible to effectively make use of the wafer prepared in the step (i) by performing a suitable dicing operation in the step (ii). When a linear cutting, which is employed in “dicing” of a current semiconductor production processes, is performed to obtain a plurality of sub-interposer precursors, unused portions of wafers may be left after cutting. However, the present invention can suitably cope with it.

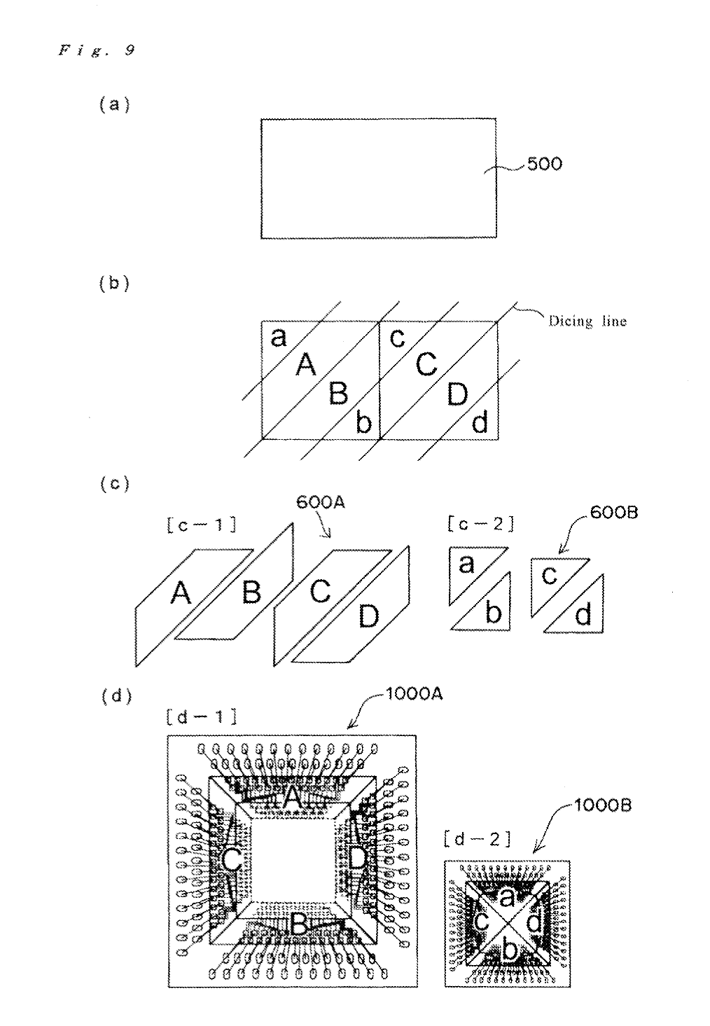

Specifically, when a rectangular wafer as illustrated in FIG. 9(a) is used and cut along the dicing lines as illustrated in FIG. 9(b), a plurality of sub-interposer precursors “A”, “B”, “C” and “D” can be obtained as illustrated in (c-1) of FIG. 9(c) as well as a plurality of sub-interposer precursors “a”, “b”, “c” and “d” having a different shape from “A”, “B”, “C” and “D” can be obtained as illustrated in (c-2) of FIG. 9(c). That is, a suitable combination of the linear dicing operations of the wafer makes it possible to make use of the whole of the rectangular wafer wherein a plurality of interposer precursors for the first interposer and a plurality of interposer precursors for the second interposer are obtained at the same time. As a result, there is eventually obtained a package 1000A as illustrated in (d-1) of FIG. 9(d) by using of the sub-interposer precursors “A” to “D” as well as a package 1000B as illustrated in (d-2) of FIG. 9(d) by using of the sub-interposer precursors “a” to “d”.

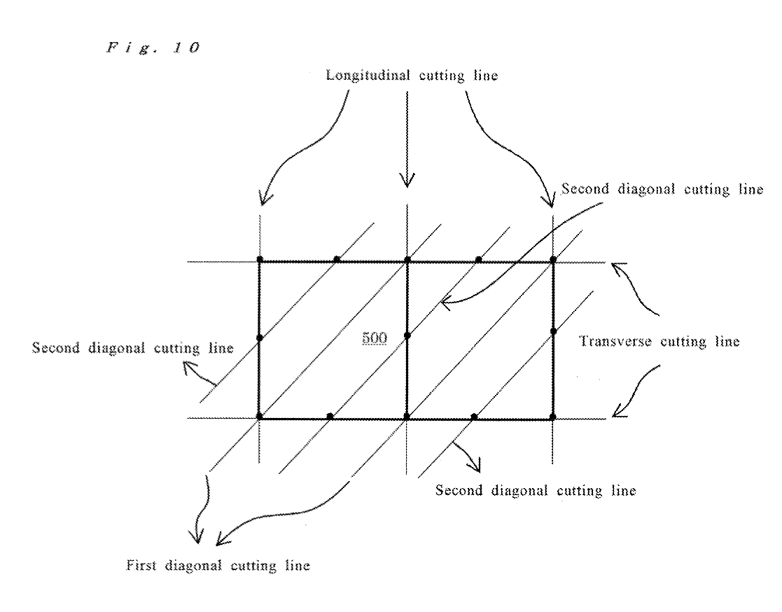

As described above, using ingenuity in dicing operation, it is possible to produce a silicon interposer with a high efficiency in terms of area, which will lead to an achievement of a further cost reduction. The above interposer precursors can also be described as follows:
Interposer precursors obtained by cutting out from the wafer into a rectangular pieces along a longitudinal cutting line and a transverse cutting line perpendicular to the longitudinal cutting line, and further cutting out therefrom along a first diagonal cutting line which connects cross points of the longitudinal and transverse cutting lines and a second diagonal cutting lines which diagonally connect points respectively on the longitudinal cutting line and the transverse cutting line each located between the cross points (see FIG. 10).”

### [Production Process of Silicon Interposer]

The present invention provides the silicon interposer used in the above package and the production method thereof.

An example of a specific production process of the silicon interposer will be described:

I. Preparation of silicon wafer

II. Dicing*

III. Formation of insulating film

IV. Formation of wiring (sputtering/etching)

V. Formation of cover layer

VI. Formation of via (in a case where a silicon through-hole via is formed) (* It is also possible that the dicing operation is carried out as a final step)
1. Formation of holes in silicon substrate
2. Plating
3. Thinning treatment of wafer
4. Formation of bump

Although a few embodiments of the present invention have been hereinbefore described, the present invention is not limited to these embodiments. It will be readily appreciated by those skilled in the art that various modifications are possible without departing from the scope of the present invention. For example, the following modified embodiments are possible.

The present invention has been described with respect to the embodiment wherein the conductive portions of the sub-interposers electrically interconnect the opposed surfaces. That is, in the above description, each sub-interposer electrically interconnects “first terminal contacts provided on the first surface” and “second terminal contacts provided on the second surface” However, the present invention is not limited to such embodiment, but the conductive portions may be provided to connect a part with another part on the same surface. In other words, the second terminal contacts, which are electrically connected to the first terminal contacts provided on the first surface, may also be provided on the first surface. In this case, the first and second terminal contacts can be connected via a wiring layer. When the second terminal contacts, which are electrically connected to the first terminal contacts, are provided on the first surface, not only a POP mounting can be easily achieved, but also a wire bonding is easily achieved on the terminal contacts.

The present invention has been described with respect to the embodiment wherein the interposer is provided as a single layer (i.e. single stage) located between the circuit substrate and electronic component. However, the present invention is not limited to such embodiment, but a plurality of layers of interposers may be provided. For example, a ceramic interposer may be mounted on a resin interposer. In a case of such multistage interposers, all interposers in every stage may be composed of the sub-interposers, or only a particular interposer in a selected stage may be composed of the sub-interposers.

In general, the present invention as described above includes the following aspects:

The first aspect: A package comprising an electronic component, a circuit substrate onto which the electronic component is mounted, and an interposer located between the electronic component and the circuit substrate, allowing them to be electrically connected with each other,

wherein the interposer is composed of at least two sub-interposers, and

the at least two sub-interposers lie in the same plane to be disposed only on electrode terminal-forming areas of both of the electronic component and the circuit substrate.

The second aspect: The package according to the first aspect, wherein the at least two sub-interposers are ones which are cut out from the same base part and thus are made of the same material as each other.

The third aspect: The package according to the first or second aspect, wherein the electronic component is a semiconductor chip; and the at least two sub-interposers comprise a semiconductor material constituting the semiconductor chip.

The fourth aspect: The package according to the third aspect, wherein the semiconductor material is a silicon.

The fifth aspect: The package according to any one of the first to fourth aspects, wherein the at least two sub-interposers lie in the same plane such that they are spaced from each other.

The sixth aspect: The package according to any one of the first to fourth aspects, wherein the at least two sub-interposers lie in the same plane such that they form a ring.

The seventh aspect: An interposer used for the package according to any one of the first to sixth aspects, wherein the interposer is composed of at least two sub-interposers, each of which has a first surface and a second surface which is opposed to the first surface; and

in each of the sub-interposers, terminal contact provided on the first surface and terminal contact provided on the second surface are electrically connected with each other.

The eighth aspect: A method for producing a package comprising the steps of:

(i) providing a wafer;

(ii) cutting the wafer to provide a plurality of interposer precursors;

(iii) forming a conductive portion in each of the interposer precursors to electrically connect the opposed surfaces thereof (i.e. opposed main surface thereof) with each other, and thereby providing a plurality of sub-interposers;

(iv) mounting at least two of the sub-interposers onto a circuit substrate; and

(v) mounting an electronic component onto the at least two of the sub-interposers,

wherein in the step (iv), the at least two of the sub-interposers are mounted such that they are disposed on an electrode terminal-forming area of the circuit substrate (namely, the at least two of the sub-interposers are arranged on the circuit substrate so that the at least two of the sub-interposers overlap only with the electrode terminal-forming area of the circuit substrate), and

in the step (v), the electronic component are mounted such that the at least two of the sub-interposers are disposed on an electrode terminal-forming area of the electronic component (namely, the electronic component is arranged on the at least two of the sub-interposers so that the at least two of the sub-interposers overlap only with the electrode terminal-forming area of the electronic component).

The ninth aspect: The method according to the eighth aspect, wherein the electronic component used in the step (v) is a semiconductor chip, and the semiconductor chip is obtained from the wafer provided in the step (i).

The tenth aspect: The method according to the eighth or ninth aspect, wherein two types of the packages, i.e., a first package comprising a first interposer and a second package comprising a second interposer are produced; and

in the step (ii), the cutting of the wafer is performed by a combination of plural linear dicing operations, and thereby providing a plurality of interposer precursors for the first interposer and a plurality of interposer precursors for the second interposer while making use of the whole of the rectangular wafer provided in the step (i).

### INDUSTRIAL APPLICABILITY

The present invention makes it possible to improve a mounting efficiency, and thus may be applied in various mounting techniques. Particularly, the present invention can be suitably used in a mounting technique where an interposer is placed between an electronic component and a circuit substrate. Therefore, the present invention is applicable to any suitable productions for various electronic equipments, for example portable electronic devices such as cell phones.

### CROSS REFERENCE TO RELATED PATENT APPLICATION

The present application claims the right of priority of Japan patent application No. 2009-210468 (filing date: Sep. 11, 2009, title of the invention: ELECTRONIC COMPONENT PACKAGE, METHOD FOR PRODUCING THE SAME AND INTERPOSER), the whole contents of which are incorporated herein by reference.

1-10. (canceled)

11. A package comprising:
an electronic component;
a circuit substrate onto which the electronic component is mounted; and
an interposer located between the electronic component and the circuit substrate, allowing them to be electrically connected with each other,
wherein the interposer is composed of at least two sub-interposers;
the at least two sub-interposers lie in the same plane to be disposed only on electrode terminal-forming areas of both of the electronic component and the circuit substrate; and
the at least two sub-interposers lie in the same plane such that they are annularly arranged.
